(19) United States
(12) Patent Application Publication
(10) Pub. No.: US 2006/0220168 A1
(43) Pub. Date: Oct. 5, 2006

(54) Shielding high voltage integrated circuits

(75) Inventor: Michael Hsing, Saratoga, CA (US)

Correspondence Address: PERKINS COIE LLP;PATENT-SEA, P.O. BOX 1247, SEATTLE, WA, 98111-1247, US

(73) Assignee: Monolithic Power Systems, Inc.

(21) Appl. No.: 11/364,120

(22) Filed: Feb. 28, 2006

Related U.S. Application Data
(60) Provisional application No. 60/661,663, filed on Mar. 8, 2005.

(51) Int. Cl. H01L 29/00

(52) U.S. Cl. 257/499

(57) ABSTRACT

Methods and apparatus are disclosed for protecting the electric field distribution of the high voltage semiconductor devices and of the high voltage junction terminating structures from the influences of overlaying interconnections. The proposed methods and apparatus prevent the breakdown voltage of the devices from decreasing. At the same time, circuit areas are reduced and parasitic resistances inherent to the conventional approach are eliminated or minimized.

### CROSS-REFERENCE TO RELATED APPLICATION(S)

The present application claims the benefit of U.S. Provisional Patent Application Ser. No. 60/661,663, filed Mar. 8, 2005, entitled “Punch-Through High Voltage Interconnection for Integrated Circuit”.

### TECHNICAL FIELD

The embodiments described here relate, in general, to high voltage integrated circuits and, in particular, to protecting the electric field distribution of the semiconductor devices from the influences of overlaying interconnection lines to prevent their breakdown voltage from decreasing.

### BACKGROUND

Insulated gate bipolar transistors (IGBTs) are popular semiconductors that combine low power and fast switching metal-oxide semiconductor field-effect transistors (FETs) with high voltage and high current bipolar junction transistors (BJT). IGBTs offer faster speeds, better drive, and better output characteristics than power BJTs, in addition to higher current densities in comparison with equivalent high-powered FETs.

A voltage applied to the gate of FETs modulates the current between the source and drain terminals and alters the shape of the conducting channel. Regarding the alteration mechanism, there are two types of FETs: (1) enhancement mode, in which the voltage applied to the gate increases the current flow from the source to the drain; and (2) depletion mode, in which the voltage applied to the gate decreases the current flow from the source to the drain of the FET. In effect, the depletion mode device is a normally closed switch and the enhancement mode device is a normally open switch.

Any arrangement of the integrated circuit (IC) components that affects the electrical field distribution of the device can also affect the device properties, such as its breakdown voltage. Therefore, in case of high voltage integrated circuits (HVICs), it is of particular interest to shield and protect the devices from the electric field disturbances caused by high voltage interconnection lines passing over them. Such disturbances can affect the electrical field distribution of the underlying devices and severely lower their breakdown voltage.

A few solutions have been proposed to shield the devices of an HVIC and prevent their breakdown voltage from decreasing. The first popular solution is the use of different types of capacitive coupled or resistive field plate rings to smooth out the underlying electric field. This approach is discussed in “Structure of 600V IC and A New Voltage Sensing Device” of 1993 ISPSD (IEEE). Problems with this method of avoiding the decline of breakdown voltage are: (1) complicating manufacturing by adding capacitive coupled or resistive field plate rings; (2) limiting the voltage to less than 600V; and (3) increasing the die size.

The second approach to solving the breakdown voltage problem, which is an improvement over the first solution, is Self-Shielding, wherein the high voltage interconnection lines do not cross over the high voltage device or the high voltage junction. This concept has been discussed in “A Versatile 700-1200V IC Process for Analog and Switching Applications” of July 1991 of IEEE Transaction on Electronic Devices. This approach has also been discussed in “Self-Shielding: New High-Voltage Inter-connection Technique for HVICs” of May 1996 of ISPSD (IEEE). While this approach allows higher operating voltages and simpler manufacturing processes, it does not reduce the size of the corresponding circuit because additional self-shielding regions are required to implement this concept. Furthermore, it creates parasitic resistors which are undesirable and need to be compensated for.

### BRIEF DESCRIPTION OF THE DRAWINGS

FIG. 1 illustrates a simplified schematic diagram of a prior art high voltage integrated circuit (HVIC) and its main building blocks.

FIG. 2A illustratively concentrates on one building block of the HVIC of FIG. 1 and a high voltage junction terminating (HVJT) structure that surrounds this block, and FIG. 2B illustrates a simplified HVJT structure according to an embodiment of the invention.

FIGS. 3A and 3B illustrate inherent parasitic resistors in simplified cross-sections of an n- and a p-channel level shifter of the prior art, respectively.

FIGS. 4A and 4B illustrate the A-A cross-sections depicted in FIGS. 2A and 2B, respectively. FIG. 4C illustrates the potential distribution of the semiconductor surface of the embodiment shown in FIG. 4B.

FIG. 5 depicts a simplified cross-sectional structure of a level shifter, according to another embodiment of the invention, and its potential distribution under low and high operating voltages, respectively.

FIG. 6A illustrates the B-B cross-section depicted in FIG. 2A and FIG. 6B illustrates a potential distribution of the semiconductor surface of the embodiment shown in FIG. 6A.

FIG. 7A illustrates the B-B cross-section depicted in FIG. 2B, and FIG. 7B illustrates a potential distribution of the semiconductor surface of the embodiment shown in FIG. 7A.

FIGS. 8A and 8B illustrate a cross-section of the prior art with a typical HVJT structure and a simplified implementation of the HVJT region according to yet another alternative embodiment of the invention, respectively.

### DETAILED DESCRIPTION

The embodiments described herein are directed to methods and apparatus for protecting the electric field distribution of high voltage semiconductor devices and of high voltage junction terminating structures from the influences of overlaying interconnections. The methods and apparatus prevent the breakdown voltage of the devices from decreasing. They also reduce the required shielding areas and eliminate or minimize parasitic resistances inherent to the conventional approach.

Various embodiments of the invention will now be described. The following description provides specific details for a thorough understanding and enabling description of these embodiments. One skilled in the art will understand, however, that the invention may be practiced without many of these details. Additionally, some well-known structures or functions may not be shown or described in detail, so as to avoid unnecessarily obscuring the relevant description of the various embodiments.

The terminology used in the description presented below is intended to be interpreted in its broadest reasonable manner, even though it is being used in conjunction with a detailed description of certain specific embodiments of the invention. Certain terms may even be emphasized below; however, any terminology intended to be interpreted in any restricted manner will be overtly and specifically defined as such in this Detailed Description section.

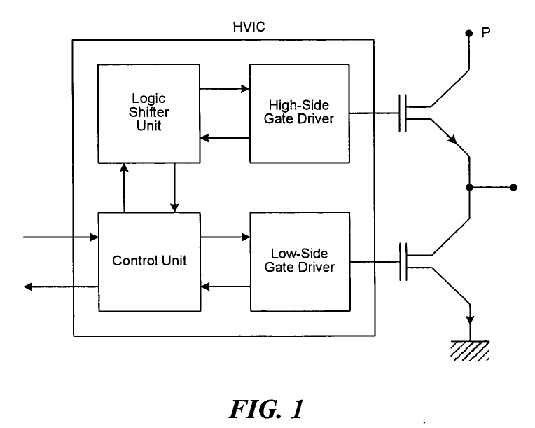

Some attributes and advantages of this invention are best understood by comparing the disclosed embodiments with the prior art. FIG. 1 illustrates a conventional high voltage integrated circuit (HVIC) connected to an insulated gate bipolar transistor (IGBT) half bridge. The high-side gate driver (HSGD) and the low-side gate driver supply the gate drive signals for their corresponding high voltage pull-up and pull-down transistors. The control unit (CU) controls the gate driver units based on I/O signals to the HVIC. The level shifting unit (LSU) functions as an interface between the CU and the gate driver units and shifts up or shifts down the voltage levels of the signals transmitted from CU to HSGD and from HSGD to CU.

Typically, to assure a high voltage that could be withstood, the HSGD is formed in an island that is electrically separated from the other circuit units. The periphery of the HSGD is surrounded by a high voltage terminating junction structure (HVJT), to which a high voltage is applied for insulating the HSGD unit from the other units.

As illustrated in this typical HVIC, a high voltage n-channel MOSFET (HVN) is provided within the LSU for shifting up the signal voltage level before sending the signal to the HSGD unit. Also, a high voltage p-channel MOSFET (HVP) is provided within the island of the HSGD unit for shifting down the signal voltage level before sending it from the HSGD unit to the LSU. In the prior art, both of these high voltage n- and p-channel MOSFETs are surrounded by their respective HVJTs.

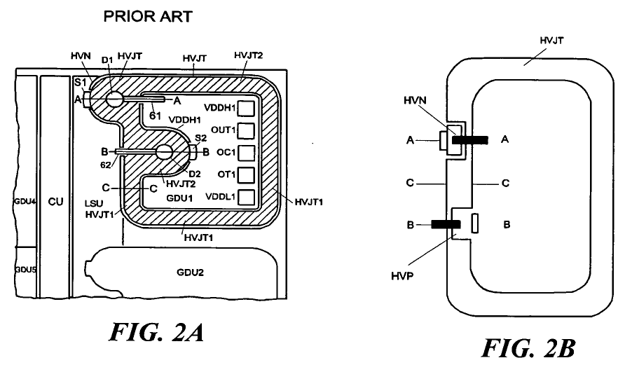

In the U.S. Pat. No. 6,124,628 to Fujihira et al (“Fujihira”), methods and apparatus are disclosed to combine the HVJT structure of the HSGD unit with those of the high voltage n-channel and p-channel MOSFETs. However, Fujihira acknowledges the formation of an inherent parasitic resistor as a result of this combination. FIG. 2A illustrates an embodiment of Fujihira's invention while also depicting the CU, the LSU, and some of the elements of the HSGD unit.

FIG. 2B illustrates a simplified plan view of an embodiment of the present invention. While the proposed HVJT structure of this embodiment does not cover all the areas covered by Fujihira in FIG. 2A, it similarly protects the devices, eliminates or minimizes parasitic resistances, and is significantly smaller in size. Specifically, it eliminates the parasitic resistor when operating below the punch-through voltage, and significantly reduces the parasitic resistor value when operating at higher voltages.

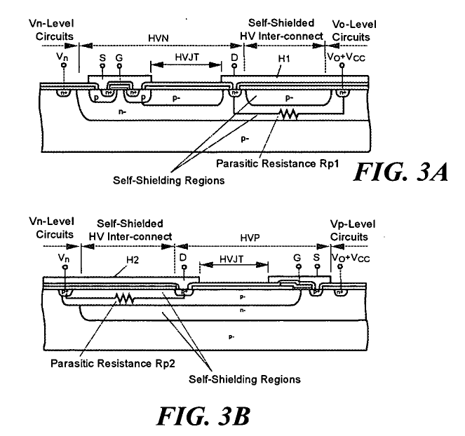

FIGS. 3A and 3B illustrate inherent parasitic resistors in simplified cross-sections of an n- and a p-channel level shifter of the prior art, respectively. FIG. 3A shows a parasitic resistor formed within the n-type region under the self-shielding between the two n⁺ regions. FIG. 3B shows a parasitic resistor formed within the p-type region under the self-shielding between the two p⁺ regions.

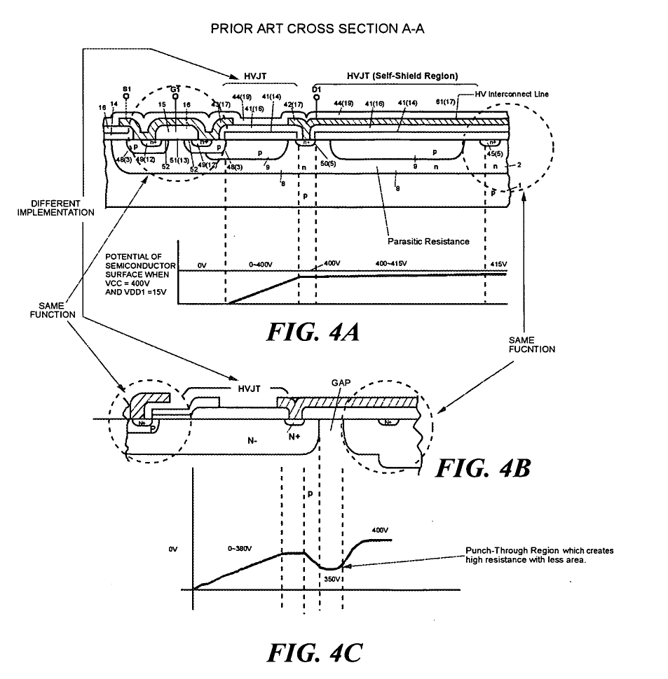

FIG. 4A illustrates the A-A cross-sections depicted in FIGS. 2A and 2B, respectively. However, as shown in FIG. 4B, in this embodiment of the invention the self-shielding region of the prior art, shown in FIG. 4A, is totally removed. The eliminated self-shielding region includes the p-type region 9 under the HV (high voltage) interconnect line. In this embodiment, as depicted in FIG. 4B, the HVJT structure adjacent to the n-channel MOSFET is also simplified by eliminating its p-type region 9. This is the area of the semiconductor in which the surface potential changes rapidly.

In the embodiment of FIG. 4B, a gap is intentionally created between the n-type regions under the HV interconnect line and the one under the HVJT structure. This gap divides the n-type region 8 of the prior art into two separate n-type regions with a high electrical resistance between them. With such a gap between the drain of the HVN and the HSGD periphery, the drain of the HVN is electrically isolated up to a predetermined punch-through voltage.

For many instances, depending on oxidation thermal cycle and the particular application, this gap is about 3 to 8 μm and the predetermined punch-through voltage is about 10V to 15V. By operating below these voltages, the parasitic resistor is practically eliminated. At higher voltages (under punch-through conditions) this gap will also reduce the parasitic resistance. Therefore, while the semiconductor size has been reduced by elimination of the self-shielding part and the p-type regions 9, the parasitic resistance has been also eliminated, which lowers the power consumption.

FIG. 4C illustrates the potential distribution of the semiconductor surface of the embodiment shown in FIG. 4B. As depicted in FIG. 4C, the semiconductor surface potential drops in the gap region and reduces the power loss.

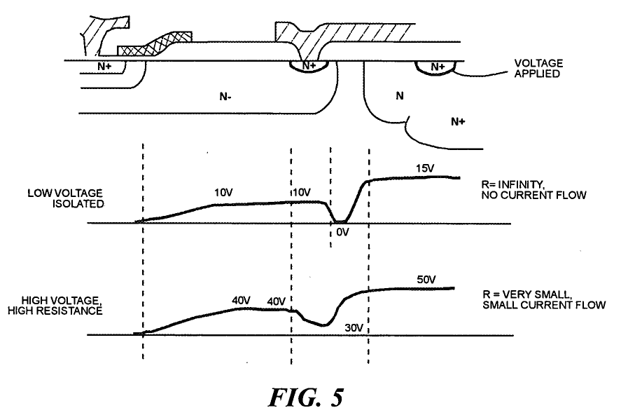

FIG. 5 depicts a simplified cross-sectional structure of a level shifter, according to the above discussed embodiment of the invention, and its potential distribution under low and high operating voltages, respectively. The main difference to be noticed as a result of comparing the low and high operating voltage graphs is the fact that at low operating voltages the semiconductor surface voltage at the gap is zero but it is more than zero at high operating voltages. This translates to infinite resistance of the gap at low operating voltages and some resistance at high operating voltages, while power is saved during both conditions.

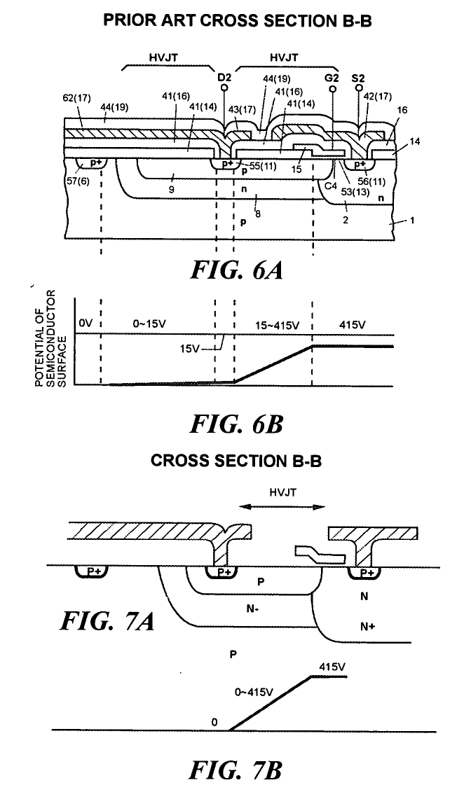

FIGS. 6A and 7A illustrate the B-B cross-section depicted in FIG. 2B, in accordance with another embodiment of the invention. FIGS. 6B and 7B, illustrate the potential distribution of the semiconductor surfaces of the cross-sections shown in FIGS. 6A and 7A. As depicted in FIG. 7A, and compared to FIG. 6A, the HVJT region of the prior art that is under the interconnection line 62 (connected to the drain) is removed. This shortens regions 8 and 9. Actually, there is no need to have this HVJT region at all because as depicted in FIG. 6B, the voltage below the p+region of the drain is not high.

FIGS. 6B and 7B indicate similar potential distributions. And, while the proposed improvements in the embodiment of FIG. 7A may not be as extensive as those of FIG. 4B, significant size reduction results in the p-channel MOSFET of this level shifter.

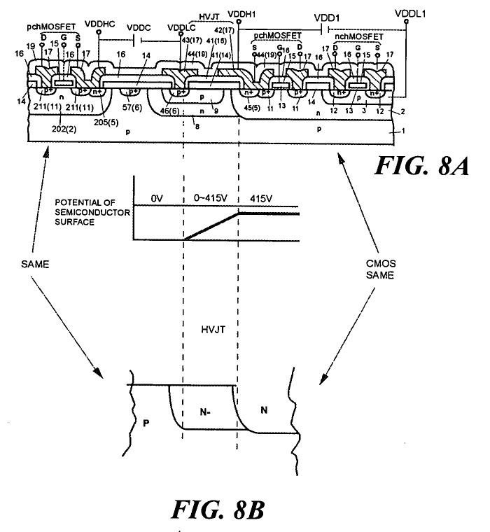

FIGS. 8A and 8B illustrate a cross-section of the prior art with a typical HVJT structure and a simplified implementation of the HVJT region according to yet another alternative embodiment of the invention, respectively. As depicted in these Figures, the p-type region 9 of the HVJT structure of the prior art is eliminated and the n-type region 8 is replaced by an n⁻ region which exhibits similar characteristics.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof.

Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize.

The teachings of the invention provided herein can be applied to other systems, not necessarily the system described above. The elements and acts of the various embodiments described above can be combined to provide further embodiments.

Changes can be made to the invention in light of the above Detailed Description. While the above description describes certain embodiments of the invention, and describes the best mode contemplated, no matter how detailed the above appears in text, the invention can be practiced in many ways. Details of the compensation system described above may vary considerably in its implementation details, while still being encompassed by the invention disclosed herein.

As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

While certain aspects of the invention are presented below in certain claim forms, the inventors contemplate the various aspects of the invention in any number of claim forms. Accordingly, the inventors reserve the right to add additional claims after filing the application to pursue such additional claim forms for other aspects of the invention

We/I claim:

1. A high voltage integrated circuit (HVIC) comprising:
means for driving a gate of a high voltage transistor;
means for controlling the gate driving means;
means for shifting up a signal voltage when the signal is transmitted from the control means to the gate driving means; and
means for shifting down a signal voltage when the signal is transmitted from the gate driving means to the control means, wherein:
the gate driving means is substantially enclosed by a high voltage junction terminating (HVJT) structure of a loop geometry;
the shifting up means is located outside the HVJT loop and is not exclusively surrounded by any part of the HVJT loop or exclusively surrounded by any other HVJT structure; and
the shifting down means is located inside the HVJT loop structure and is not exclusively surrounded by any part of the HVJT loop or exclusively surrounded by any other HVJT structure.

2. A high voltage integrated circuit (HVIC) comprising:
at least one high-side gate drive (HSGD) unit for driving a gate of a high voltage transistor;
a control unit (CU) for controlling the at least one HSGD unit based on I/O signals to the HVIC; and
a level shifter unit (LSU) acting as an interface between the CU and the HSGD for shifting up a signal voltage when the signal is transmitted from the CU to the HSGD, and for shifting down a signal voltage when the signal is transmitted from the HSGD to the CU, wherein:
the HSGD is surrounded by a high voltage junction terminating (HVJT) loop structure;
the shifting up of the signal voltage is performed by a MOS (metal-oxide semiconductor) or a MIS (metal-insulator semiconductor) of a first channel type that is located outside the HVJT loop structure and is not exclusively surrounded by a part of the HVJT loop or exclusively surrounded by another HVJT structure; and
the shifting down of the signal voltage is performed by a MOS or a MIS of a second channel type that is located inside the HVJT loop structure and is not exclusively surrounded by a part of the HVJT loop or exclusively surrounded by another HVJT structure.

3. The HVIC of claim 2, wherein the HSGD drives the gate of a pull-up part of an insulated gate bipolar transistor (IGBT) half-bridge.

4. The HVIC of claim 2, further comprising at least one Low-side gate drive (HSGD) unit for driving a gate of a pull-down part of the IGBT half-bridge.

5. The HVIC of claim 2, wherein the shifting up of the signal voltage is performed by an N-channel FET and the shifting down of the signal voltage is performed by a P-channel FET.

6. The HVIC of claim 5, wherein:
the N-channel FET is formed on a first region of a first conductivity type;
the first region of the first conductivity type is formed on a semiconductor substrate of a second conductivity type;
a signal interconnect line transmits the shifted-up signal from a drain of the N-channel FET to within the HVJT loop and over a second region of the first conductivity type; and
the first region of the first conductivity type is separated from the second region of the first conductivity type by a predetermined distance.

7. The HVIC of claim 2, wherein the first conductivity type is N-type and the second conductivity type is P-type.

8. The HVIC of claim 5, wherein:
the P-channel FET is formed on a first region of a first conductivity type;
the first region of the first conductivity type is formed on a semiconductor substrate of a second conductivity type;
a signal interconnect line transfers the shifted-down signal from a drain of the P-channel FET to the LSU; and
the first region of the first conductivity type does not extend beyond the drain of the P-channel FET.

9. A high voltage gate driving apparatus comprising:
at least one high voltage gate drive unit for driving a gate of a high voltage transistor;
a high voltage junction terminating (HVJT) loop structure surrounding the high voltage gate drive unit;
a MOS (metal-oxide semiconductor) or a MIS (metal-insulator semiconductor) FET transistor of a first channel type for shifting up a signal voltage that enters into the HVJT loop, wherein the transistor is located outside the HVJT loop structure and is not exclusively surrounded by any part of the HVJT loop or exclusively surrounded by another HVJT structure; and
a MOS or MIS FET transistor of a second channel type for shifting down a signal voltage that exits out of the HVJT loop, wherein the transistor is located inside the HVJT loop structure and is not exclusively surrounded by any part of the HVJT loop or exclusively surrounded by another HVJT structure.

10. The apparatus of claim 9, wherein the high voltage gate drive unit drives a transistor gate of an insulated gate bipolar transistor (IGBT) half-bridge.

11. The apparatus of claim 9, further comprising a low voltage gate drive unit which drives another transistor gate of the IGBT half-bridge.

12. The apparatus of claim 9, wherein the shifting up transistor is an N-channel FET and the shifting down transistor is a P-channel FET.

13. The apparatus of claim 12, wherein:
the N-channel FET is formed on a first region of a first conductivity type;
the first region of the first conductivity type is formed on a semiconductor substrate of a second conductivity type;
a signal interconnect line transfers the shifted up signal from a drain of the N-channel FET to within the HVJT loop over a second region of the first conductivity type; and
the first region of the first conductivity type is separated from the second region of the first conductivity type by a gap of a predetermined size to create electrical resistance between the two regions.

14. The apparatus of claim 13, wherein the first conductivity type is N-type and the second conductivity type is P-type.

15. The apparatus of claim 13, wherein the gap size is about 3-8 μm.

16. The apparatus of claim 12, wherein:
the P-channel FET is formed on a first region of a first conductivity type;
the first region of the first conductivity type is formed on a semiconductor substrate of a second conductivity type;
a signal interconnect line transfers the shifted down signal from a drain of the P-channel FET to outside the HVJT loop; and
the first region of the first conductivity type does not extend beyond the drain of the P-channel FET.

17. The apparatus of claim 12, wherein at least in a segment of the HVJT loop the HVJT structure comprises a region of the first conductivity type formed over the semiconductor substrate of the second conductivity type, and wherein the region of the first conductivity type is covered by an insulating layer.

18. The apparatus of claim 17, wherein the first conductivity type is N type and the second conductivity type is P type.

19. A method of driving a gate of a high voltage transistor, the method comprising:
electrically isolating a semiconductor area for generating gate driving signals, wherein the area is isolated by a high voltage junction terminating (HVJT) structure that surrounds the area;
transmitting gate driving control signals into the isolated area from a first voltage level shifter situated outside the isolated area, wherein the first voltage level shifter increases the signal voltage; and
transmitting gate drive control signals out of the isolated area from a second voltage level shifter situated inside the isolated area, wherein the second voltage level shifter decreases the signal voltage, and wherein:
the shifting up of the signal voltage is performed by a MOS (metal-oxide semiconductor) or a MIS (metal-insulator semiconductor) of a first channel type that is located outside the HVJT loop structure and is not exclusively surrounded by a part of the HVJT loop or exclusively surrounded by another HVJT structure; and
the shifting down of the signal voltage is performed by a MOS or a MIS of a second channel type that is located inside the HVJT loop structure and is not exclusively surrounded by a part of the HVJT loop or exclusively surrounded by another HVJT structure.

20. The method of claim 19, wherein the shifting up of the signal voltage is performed by an N-channel FET and the shifting down of the signal voltage is performed by a P-channel FET, and wherein:
the N-channel FET is formed on a first region of a first conductivity type;
the first region of the first conductivity type is formed on a semiconductor substrate of a second conductivity type;
a signal interconnect line transmits the shifted-up signal from a drain of the N-channel FET to within the HVJT loop and over a second region of the first conductivity type;
the first region of the first conductivity type is separated from the second region of the first conductivity type by a predetermined distance.
the P-channel FET is formed on a third region of a first conductivity type;
the third region of the first conductivity type is formed on the semiconductor substrate of the second conductivity type;
a signal interconnect line transfers the shifted-down signal from a drain of the P-channel FET to the LSU; and
the third region of the first conductivity type does not extend beyond the drain of the P-channel FET.
